(19) United States
(12) Patent Application Publication
(10) Pub. No.: US 2026/0190415 A1
(43) Pub. Date: Jul. 2, 2026

(54) SEMICONDUCTOR DEVICE AND METHOD OF FORMING THE SAME

(71) Applicant: Powerchip Semiconductor Manufacturing Corporation, Hsinchu (TW)

(72) Inventor: Meng-Han Lin, Hsinchu City (TW)

(73) Assignee: Powerchip Semiconductor Manufacturing Corporation, Hsinchu (TW)

(21) Appl. No.: 19/063,223

(22) Filed: Feb. 25, 2025

(30) Foreign Application Priority Data
Jan. 2, 2025 (TW) 114100052

(51) Int. Cl. H10D 64/00; H10D 30/01; H10D 30/65

(52) U.S. Cl. CPC H10D 64/115; H10D 30/0281; H10D 30/65

(57) ABSTRACT

A semiconductor device and a method of forming the same are provided. The semiconductor device comprises a semiconductor substrate; a gate structure on the semiconductor substrate; a source region and a drain region in the semiconductor substrate and on opposite sides of the gate structure; a sacrificial oxide layer on the semiconductor substrate; a contact etch stop layer on the sacrificial oxide layer; a lower interlayer dielectric layer on the contact etch stop layer; a high resistance dielectric layer on the gate structure and the lower interlayer dielectric layer; and a high resistance field plate, wherein at least a part of the high resistance field plate is on the high resistance dielectric layer.

### CROSS-REFERENCE TO RELATED APPLICATION

This application claims the priority benefit of Taiwan application serial no. 114100052, filed on Jan. 2, 2025. The entirety of the foregoing patent application is hereby incorporated by reference herein and made a part of this specification.

### TECHNICAL FIELD

The disclosure relates to a semiconductor device, and in particular, to a semiconductor device and a method of forming the same.

### BACKGROUND

In the semiconductor devices, a contact field plate (CFP) can be used to increase the breakdown voltage (VBD) of the high voltage device and decrease the resistance between the source and the drain (Rdson) when the device is in the on state.

However, in the drain region of high voltage devices, it is difficult to control the contact field plate, which passes through the contact etch stop layer (CESL), is accurately positioned on the sacrificial oxide layer. The position of the contact field plate is often too low and penetrates the sacrificial oxide layer. Therefore, the use of contact field plates is often accompanied by the risk of reduced performance of high voltage devices.

### SUMMARY

The disclosure provides a semiconductor device and a method of forming the same to solve the above-mentioned problem that the position of the contact field plate is difficult to accurately control, resulting in reduced performance of the high voltage device.

The disclosure provides a semiconductor device, comprising: a semiconductor substrate; a gate structure on the semiconductor substrate; ta source region and a drain region in the semiconductor substrate and on opposite sides of the gate structure; a sacrificial oxide layer on the semiconductor substrate; a contact etch stop layer on the sacrificial oxide layer; a lower interlayer dielectric layer located on the contact etch stop layer; a high resistance dielectric layer on the gate structure and the lower interlayer dielectric layer; a high resistance field plate, wherein at least a part of the high resistance field plate is on the high resistance dielectric layer.

According to an embodiment of the disclosure, the high resistance field plate is completely on the high resistance dielectric layer.

According to an embodiment of the disclosure, another part of the high resistance field plate is in the high resistance dielectric layer and the lower interlayer dielectric layer.

According to an embodiment of the disclosure, a bottom of the other part of the high resistance field plate is directly located on the sacrificial oxide layer.

According to an embodiment of the disclosure, a bottom of the other part of the high resistance field plate is located directly on the contact etch stop layer.

According to an embodiment of the disclosure, a bottom of the other portion of the high resistance field plate is between the contact etch stop layer and the high resistance dielectric layer.

According to an embodiment of the disclosure, it further comprises: an upper interlayer dielectric layer located on the high resistance dielectric layer and the high resistance field plate; a source contact plug in the upper interlayer dielectric layer, the high resistance dielectric layer, the lower interlayer dielectric layer and the contact etching stop layer, and electrically contacted to the source region; a drain contact plug in the upper interlayer dielectric layer, the high resistance dielectric layer, the lower interlayer dielectric layer and the contact etching stop layer, and electrically contacted to the drain region; and high voltage device contact plugs in the upper interlayer dielectric layer, and electrically contacted to the high resistance field plate, wherein the high voltage device contact plug and the drain contact plug are electrically connected with a metal layer.

According to an embodiment of the disclosure, it further comprises: an upper interlayer dielectric layer on the high resistance dielectric layer and the high resistance field plate; a source contact plug is in the upper interlayer dielectric layer, the high resistance dielectric layer, the lower interlayer dielectric layer and the contact etching stop layer, and electrically contacted to the source region; a drain contact plug in the upper interlayer dielectric layer, the high resistance dielectric layer, the lower interlayer dielectric layer and the contact etching stop layer, and electrically contacted to the drain region; and a high voltage device contact plugs in the upper interlayer dielectric layer, and electrically contacted to the high resistance field plate, wherein the high voltage device contact plug and the source contact plug are electrically connected with a metal layer.

According to an embodiment of the disclosure, it further comprises: an upper interlayer dielectric layer on the high resistance dielectric layer and the high resistance field plate; a source contact plug in the upper interlayer dielectric layer, the high resistance dielectric layer, the lower interlayer dielectric layer and the contact etching stop layer, and electrically contacted to the source region; and a drain contact plug in the upper interlayer dielectric layer, the high resistance dielectric layer, the lower interlayer dielectric layer and the contact etching stop layer, and electrically contacted to the drain region, wherein the high resistance field plate is not electrically connected to the source contact plug nor to the drain contact plug.

According to an embodiment of the disclosure, the gate structure comprises a metal gate.

According to an embodiment of the disclosure, the high resistance field plate comprises titanium nitride (TiN).

The disclosure provides also a method of forming semiconductor device, comprising: providing a semiconductor substrate; forming a gate structure on the semiconductor substrate; forming a source region and a drain region in the semiconductor substrate on opposite sides of the gate structure; forming a sacrificial oxide layer on the semiconductor substrate; forming a contact etch stop layer on the sacrificial oxide layer; forming a lower interlayer dielectric layer on the contact etch stop layer; form a high resistance dielectric layer on the gate structure and the lower interlayer dielectric layer; and forming a high resistance field plate, wherein at least a part of the high resistance field plate is on the high resistance dielectric layer, and wherein another part of the high resistance field plate is in the high resistance dielectric layer and the lower interlayer dielectric layer.

According to an embodiment of the disclosure, a bottom of the other part of the high resistance field plate is directly located on the sacrificial oxide layer.

According to an embodiment of the disclosure, a bottom of the other part of the high resistance field plate is located directly on the contact etch stop layer.

According to an embodiment of the disclosure, a bottom of the other part of the high resistance field plate is between the contact etch stop layer and the high resistance dielectric layer.

According to an embodiment of the disclosure, the method further comprises: forming an upper interlayer dielectric layer on the high resistance dielectric layer and the high resistance field plate; forming a source contact plug in the upper interlayer dielectric layer, the high resistance dielectric layer, the lower interlayer dielectric layer and the contact etch stop layer, and electrically contacted to the source region; forming a drain contact plug in the upper interlayer dielectric layer, the high resistance dielectric layer, the lower interlayer dielectric layer and the contact etch stop layer, and electrically contacted to the drain region; and forming a high voltage device contact plug in the upper interlayer dielectric layer, and electrically contacting the high resistance field plate, wherein the high voltage device contact plug and the drain contact plug are electrically connected with a metal layer.

According to an embodiment of the disclosure, the method further comprises: forming an upper interlayer dielectric layer on the high resistance dielectric layer and the high resistance field plate; forming a source contact plug in the upper interlayer dielectric layer, the high resistance dielectric layer, the lower interlayer dielectric layer and the contact etch stop layer, and electrically contacted to the source region; forming a drain contact plug in the upper interlayer dielectric layer, the high resistance dielectric layer, the lower interlayer dielectric layer and the contact etch stop layer, and electrically contacted to the drain region; and forming a high voltage device contact plug in the upper interlayer dielectric layer, and electrically contacted to the high resistance field plate, wherein the high voltage device contact plug and the source contact plug are electrically connected with a metal layer.

According to an embodiment of the disclosure, the method further comprises: forming an upper interlayer dielectric layer on the high resistance dielectric layer and the high resistance field plate; forming a source contact plug in the upper interlayer dielectric layer, the high resistance dielectric layer, the lower interlayer dielectric layer and the contact etch stop layer, and electrically contacted to the source region; and forming a drain contact plug in the upper interlayer dielectric layer, the high resistance dielectric layer, the lower interlayer dielectric layer and the contact etching stop layer, and electrically contacted to the drain region, wherein the high resistance field plate is not electrically connected to the source contact plug nor to the drain contact plug.

According to an embodiment of the disclosure, the gate structure comprises a metal gate.

According to an embodiment of the disclosure, the high resistance field plate comprises titanium nitride (TiN).

Based on the above, the semiconductor device of the disclosure replaces the traditional contact field plate with a high resistance field plate, which not only solves the problem of reduced performance of high voltage devices caused by the difficulty in controlling the position of the contact field plate, but also increases the breakdown voltage and the lower Rdson.

Furthermore, the method of forming semiconductor device provided by the disclosure has the advantages of being compatible with the high-k metal gate (HKMG) process and may form the above-mentioned semiconductor device without an additional mask.

Moreover, the above-mentioned semiconductor devices and their formation methods may also be used in various advanced processes, such as high-k metal gate planar field-effect transistor (HKMG planar FET), fin field-effect transistor (FinFET), gate-all-around nanosheet (GAA nanosheet), etc.

In order to make the above-mentioned features and advantages of the disclosure more specific and easy to understand, embodiments are given below and described in detail with reference to the accompanying drawings.

### BRIEF DESCRIPTION OF THE DRAWINGS

FIG. 1A to FIG. 1J are flow sectional views of a method of forming semiconductor device according to an embodiment of the disclosure.

FIG. 2 is a cross-sectional view of a semiconductor device according to an embodiment of the disclosure.

FIG. 3 is a cross-sectional view of a semiconductor device according to another embodiment of the disclosure.

FIG. 4 is a cross-sectional view of a semiconductor device according to another embodiment of the disclosure.

FIG. 5A to FIG. 5B are flow sectional views of a method of forming semiconductor device according to another embodiment of the disclosure.

FIG. 6 is a cross-sectional view of a semiconductor device according to another embodiment of the disclosure.

FIG. 7 is a cross-sectional view of a semiconductor device according to another embodiment of the disclosure.

FIG. 8 is a cross-sectional view of a semiconductor device according to another embodiment of the disclosure.

FIG. 9A to FIG. 9B are flow sectional views of a method of forming semiconductor device according to another embodiment of the disclosure.

FIG. 10 is a cross-sectional view of a semiconductor device according to another embodiment of the disclosure.

FIG. 11 is a cross-sectional view of a semiconductor device according to another embodiment of the disclosure.

FIG. 12 is a cross-sectional view of a semiconductor device according to another embodiment of the disclosure.

FIG. 13A to FIG. 13B are flow sectional views of a method of forming semiconductor device according to another embodiment of the disclosure.

FIG. 14 is a cross-sectional view of a semiconductor device according to another embodiment of the disclosure.

FIG. 15 is a cross-sectional view of a semiconductor device according to another embodiment of the disclosure.

FIG. 16 is a cross-sectional view of a semiconductor device according to another embodiment of the disclosure.

### DESCRIPTION OF THE EMBODIMENTS

Embodiments are listed below and described in detail with reference to the drawings. However, the provided embodiments are not intended to limit the scope of the disclosure.

In order to facilitate understanding, the same devices will be described with the same symbols in the following description, and will not be repeated one by one in the following paragraphs.

In addition, the drawings are for illustrative purposes only and are not drawn to original size. In fact, the dimensions of the various features may be arbitrarily increased or reduced for clarity of discussion.

In addition, for ease of description, spatially relative terms such as “upper”, “lower” and similar are used in this article to describe the relative relationship between one device and another device as shown in the drawings, not to limit the disclosure. Therefore, it will be understood that “on” may be used interchangeably with “under” and that when a device is “on” another device, it may be placed directly on the other device, or intervening devices may be present. On the other hand, when a device is said to be placed “directly on” another device, there are no intervening devices between the two.

The terminology used herein is used only to describe illustrative embodiments and does not limit the disclosure. In such cases, the singular form includes the plural form unless the context dictates otherwise.

The various manufacturing steps described below include applications such as deposition processes, removing processes, and patterning processes.

The deposition process refers to the process of forming one material onto another material, which may include spin coating, sputtering, chemical vapor deposition (CVD), physical vapor deposition (PVD), plasma enhanced chemical vapor deposition (PE-CVD), atomic layer deposition (ALD), molecular beam deposition (MBD), pulsed laser deposition (PLD), liquid source misted chemical deposition (LSMCD), etc., but are not limited thereto.

The removal process may include wet etching, dry etching, chemical mechanical planarization (CMP), etc., but is not limited thereto.

The patterning process includes techniques such as photolithography and etching to transfer the layout pattern to the mask to the material layer.

First, in order to illustrate that the method of forming semiconductor device of the disclosure has the advantage of being compatible with a high-k metal gate (HKMG) process, the method of forming semiconductor device described below is the formation of the high voltage devices C, C1, C2, C3, D, D1, D2, D3, E, E1, E2, E3, F, F1, F2, F3 on the semiconductor substrate 100, while the core device A and high resistance device B are formed in the different position for example. But the actual applications are not limited to these devices.

Moreover, the description of the disclosure takes the high voltage devices C, C1, C2, C3, D, D1, D2, D3, E, E1, E2, E3, F, F1, F2, and F3 as examples, but the applications are not limited thereto. It may be used in various advanced processes, such as high-k metal gate planar field-effect transistor (HKMG planar FET), fin field-effect transistor (FinFET), gate-all-around nanosheet (GAA nanosheet), etc.

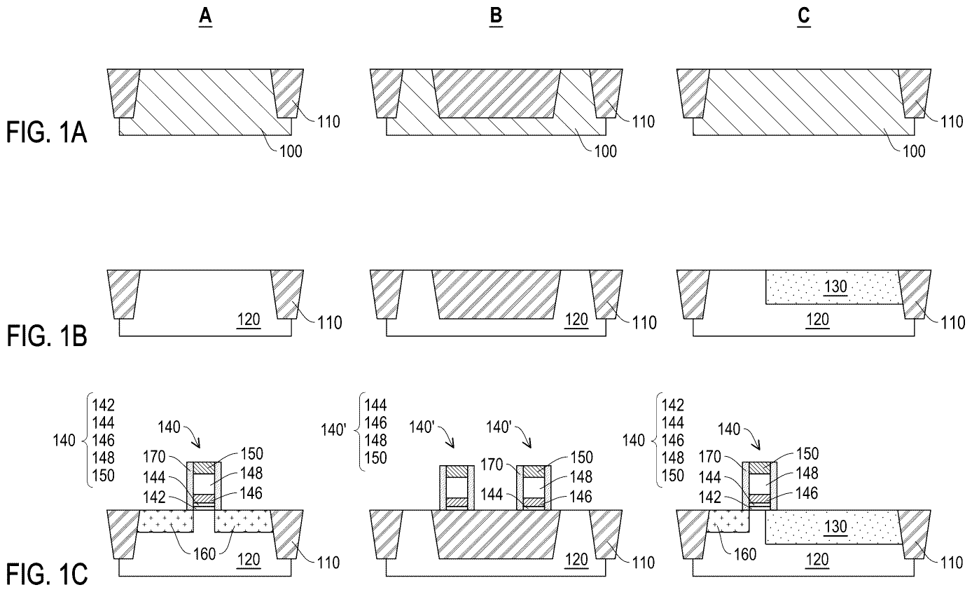

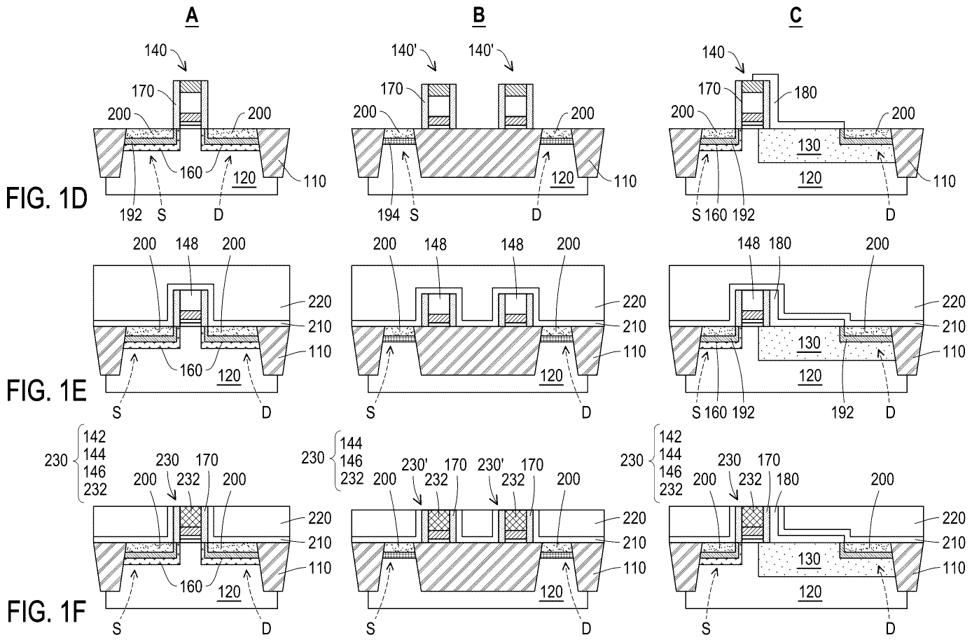

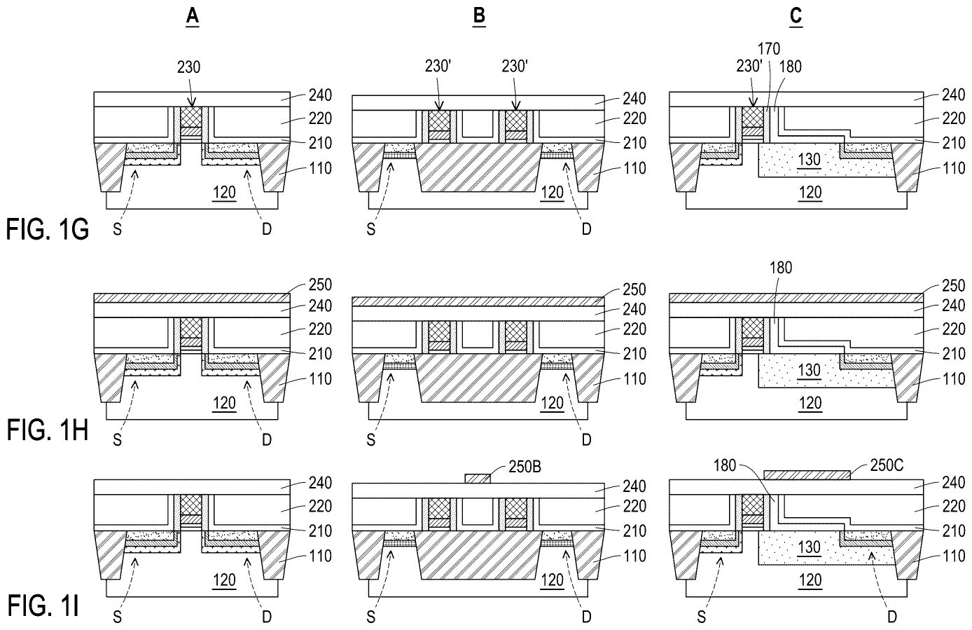

Referring to FIG. 1A, the isolation region 110 of various sizes and spacings are formed in the semiconductor substrate 100 according to the requirements of different devices of the core device A, the high resistance device B, and the high voltage device C.

In some embodiments, the isolation region 110 may be the isolation structures such as shallow trench isolation (STI), but is not limited thereto.

Next, referring to FIG. 1B, the core device A, the high resistance device B and the high voltage device C of the semiconductor substrate 100 may be ion implanted with various energies and ranges simultaneously or respectively based on the requirements. For example, the core element A, the high resistance element B and the high voltage device C of the semiconductor substrate 100 may be first implanted ions of a relatively large energy and a relatively large range to form the well implantation region 120; then, only the high voltage device C of the semiconductor substrate 100 is ion implanted with ions of a relatively small energy and a relatively small range to form a high voltage lightly doped drain region 130. But the ion implantations of the semiconductor substrate 100 are not limited thereto.

Referring to FIG. 1C, the dielectric layer 142 may be formed on the core device A and the high voltage device C first. Then, a high dielectric constant layer 144, a nitride layer 146, a dummy gate layer 148 and a hard mask layer 150 are sequentially stacked in the core device A, the high resistance device B and the high voltage device C.

In some embodiments, the nitride layer 146 may include materials such as titanium nitride (TiN).

Next, still referring to FIG. 1C, the hard mask layer 150 is patterned according to the layout pattern to form the patterned hard mask 150. Then, according to the patterned hard mask 150, the dummy gate layer 148, the nitride layer 146, the high dielectric constant layer 144 and the dielectric layer 142 of the core device A and the high voltage device C are etched, to define the dummy gate structure 140 including a dummy gate 148 on the semiconductor substrate 100 between the isolation region 110. At the same time, according to the patterned hard mask 150, the dummy gate layer 148, the nitride layer 146 and the high dielectric constant layer 144 of the high resistance device B are etched to define the dummy gate structure 140′ including a dummy gate 148 on the semiconductor substrate 100 in the isolation region 110.

In order to make the diagram symbols concise and easy to understand, the above descriptions of each material layer of the gate etching are marked with the same symbols.

Still referring to FIG. 1C, if necessary, a lightly doped drain (LDD) region 160 may be formed in the well implant region 120 of the core device A and the high voltage device C. If necessary, the spacer layer 170 may be formed on the sidewalls of the dummy gate structure 140 of the core device A and the high voltage device C, and on the sidewalls of the dummy gate structure 140′ of the high resistance device B.

Next, a sacrificial oxide layer 180 is formed on the semiconductor substrate 100 of the high voltage device C. The sacrificial oxide layer 180 may be formed, for example, on a part of the high voltage lightly doped drain region 130 of the high voltage device C, on the side of the spacer layer 170 close to the high voltage lightly doped drain region 130, and on a part of the top of the dummy gate structure 140, as shown in FIG. 1D.

Next, still referring to FIG. 1D, the source/drain implantation may be executed in the core device A, the high resistance device B and the high voltage device C to form a source region S and a drain region D in the semiconductor substrate 100 on opposite sides of the dummy gate structures 140 and 140′.

For example, the N+ type ion implantation may be executed into the lightly doped drain region 160 of the core element A, and the lightly doped drain region 160 and the high voltage lightly doped drain region 130 of the high voltage device C, and the P+ type ion implantation may be executed into the well implantation region 120 of the high resistance device B, to form the source region S and the drain region D.

Still referring to FIG. 1D, as needed, a series of processes and reactions may be selectively performed on the source region S and the drain region D of the core device A, the high resistance device B, and the high voltage device C, so as to form the metal silicide layer 200 on the surface of the region S and the drain region D, to reduce the contact resistance of the source region S and the drain region D. So that subsequent contact plugs electrically connected to the source region S and the drain region D, the device characteristics will not deteriorate due to the increase in series resistance.

Next, please refer to FIG. 1E. First, the patterned hard mask 150 of the core device A, the high resistance device B, and the high voltage device C is removed, and the top of the spacer layer 170 is flush with the top of the dummy gate 148.

Then, a contact etch stop layer (CESL) layer 210 is conformally formed on the core device A, the high resistance device B and the high voltage device C to protect the devices from etching damage during the subsequent formation of contact vias.

In the high voltage device C, at least a part of the contact etch stop layer 210 is on the sacrificial oxide layer 180.

Next, a lower interlayer dielectric layer 220 is formed on the contact etch stop layer 210, as shown in FIG. 1E.

Please refer to FIG. 1E and FIG. 1F at the same time. The core device A, the high resistance device B and the high voltage device C are completely planarized by methods such as chemical mechanical polishing (CMP), to make the tops of the lower interlayer dielectric layer 220, the contact etch stop layer 210, the spacer layer 170 and the dummy gate 148 are coplanar.

Next, the dummy gate 148 is removed, and a metal gate 232 is formed at the same position, to form a gate structure 230 including the metal gate 232 on the semiconductor substrate 100 of the core device A and the high voltage device C, and to form a gate structure 230′ including a metal gate 232 on the semiconductor substrate 100 of the high resistance element B. As shown in FIG. 1F, the gate structure 230 of the core device A and the high voltage device C may include the dielectric layer 142, the high dielectric constant layer 144, the nitride layer 146 and the metal gate 232 in sequence; the gate structure 230′ of the high resistance device B may include the high dielectric constant layer 144, the nitride layer 146 and the metal gate 232 in sequence.

Then, as shown in FIG. 1G, in the core element A, the high resistance element B and the high voltage device C, a high resistance dielectric layer 240 is comprehensively formed on the gate structures 230 and 230′ and the lower interlayer dielectric layer 220.

As shown in FIG. 1H, in the core device A, the high resistance device B and the high voltage device C, a high resistance layer 250 is formed comprehensively. The high resistance layer 250 may be a high resistance material such as titanium nitride (TiN), but is not limited thereto.

As shown in FIG. 1I, the high resistance layer 250 is patterned by photolithography and etching to form the required high resistance layer 250B and high resistance field plate 250C in the high resistance element B and the high voltage device C respectively.

Then, as shown in FIG. 1J, an upper interlayer dielectric layer 260 is formed on the high resistance dielectric layer 240 of the core device A, the high resistance dielectric layer 240 and the high resistance layer 250B of the high resistance device B, and the high resistance dielectric layer 240 and the high resistance field plate 250C of the high voltage device C.

Next, as still shown in FIG. 1J, contact plugs 270 may be formed in the core device A, the high resistance device B and the high voltage device C by various photolithographic and etching processes.

These contact plugs 270 may comprise the source contact plug 270S and the drain contact plug 270D in the upper interlayer dielectric layer 260, the high resistance dielectric layer 240, the lower interlayer dielectric layer 220 and the contact etch stop layer 210 of the core device A, the high resistance device B and the high voltage device C. The source contact plug 270S and the drain contact plug 270D in are respectively connected to the source region S and the drain region D of the core device A, the high resistance device B and the high voltage device C, as shown in FIG. 1J.

Moreover, these contact plugs 270 may also include high resistance device contact plug 270C in the upper interlayer dielectric layer 260 of the high resistance device C, and the high resistance device contact plug 270C are connected to the high resistance field plate 250C of the high resistance device C, as shown in FIG. 1J. Or, the high resistance device contact plug 270C may be not formed (not shown in the drawings).

Next, a patterned metal layer will be formed on the contact plugs 270 of the core device A, the high resistance device B and the high voltage device C, as shown in FIG. 1J. In order to focus on the semiconductor device of the disclosure and its formation, the following only describes the subsequent process of the high voltage device C shown in FIG. 1J, especially focus design of electrical connections on the high resistance field plate 250C completely located on the high resistance dielectric layer 240.

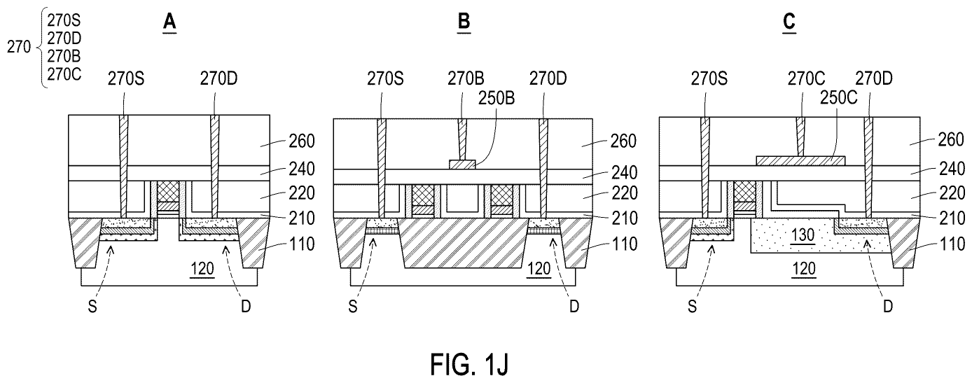

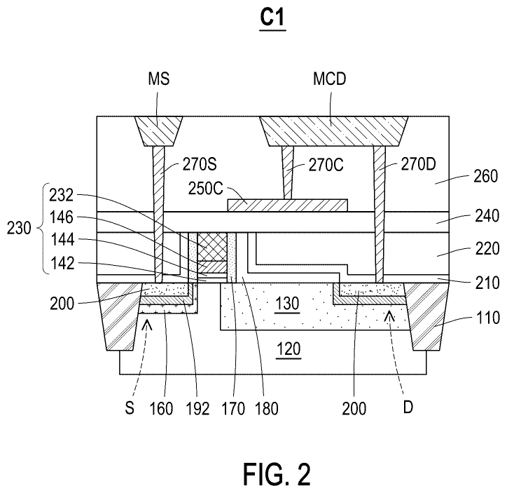

The high voltage device C1 in FIG. 2 is formed a metal layer MS on the source contact plug 270S, and a metal layer MCD on the high voltage device contact plug 270C and the drain contact plug 270D. That is, the high voltage device contact plug 270C and the drain contact plug 270D are electrically connected with the metal layer MCD.

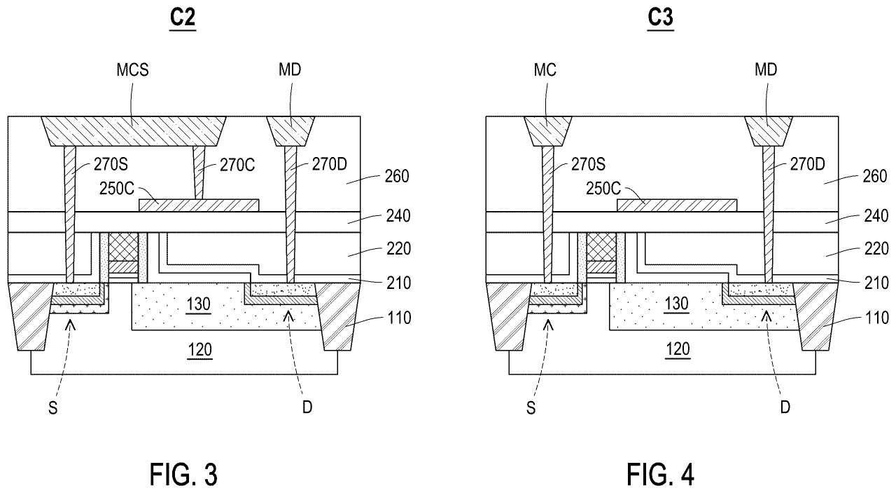

The high voltage device C2 in FIG. 3 id formed a metal layer MCS on the high voltage device contact plug 270C and the source contact plug 270S, and a metal layer MD on the drain contact plug 270D. That is, the high voltage device contact plug 270C and the source contact plug 270S are electrically connected with the metal layer MCS.

The high voltage device C3 in FIG. 4 is not the same as the FIG. 1J, only the source contact plug 270S and the drain contact plug 270D formed in the high voltage device C, there is no high voltage device contact plug 270C formed in the high voltage device C. Only the metal layer MC and the metal layer MD are formed on the source contact plug 270S and the drain contact plug 270D respectively. That is, the high resistance field plate 250C does not electrically contact to the source contact plug 270S nor to the drain plug 270D.

That is, the high voltage device C shown in FIG. 1J may be made into three different high voltage devices: a high voltage device C1 with a high resistance field plate 250C electrically connected to the drain region D as shown in FIG. 2, a high voltage device C2 with a high resistance field plate 250C electrically connected to the source region S as shown in FIG. 3, or a high voltage device C3 with a high resistance field plate 250C in a floating state as shown in FIG. 4. Since the high resistance field plates 250C of the three high voltage devices C1, C2, and C3 are located on the high resistance dielectric layer 240 and are at a certain distance from the sacrificial oxide layer 180, so that the contact etch stop layer 180 is not be passed through during the formation process of he high resistance field plate 250C. Therefore, the high voltage devices C1, C2 and C3 are not damaged. In addition, as mentioned above, the formation method is compatible with the high-k metal gate (HKMG) process, and it may be completed without additional masks.

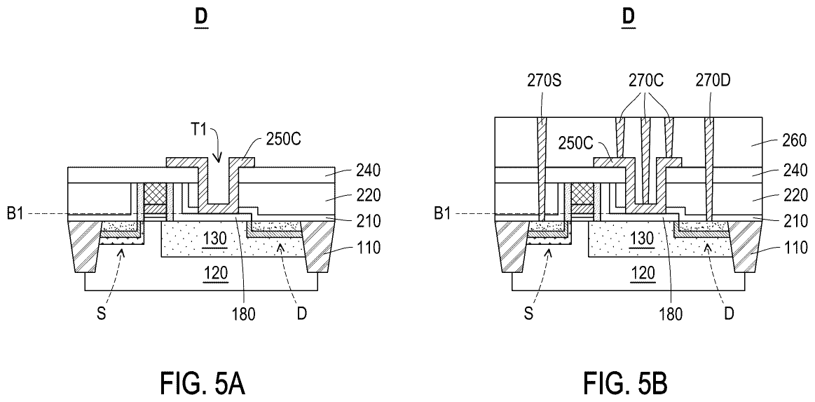

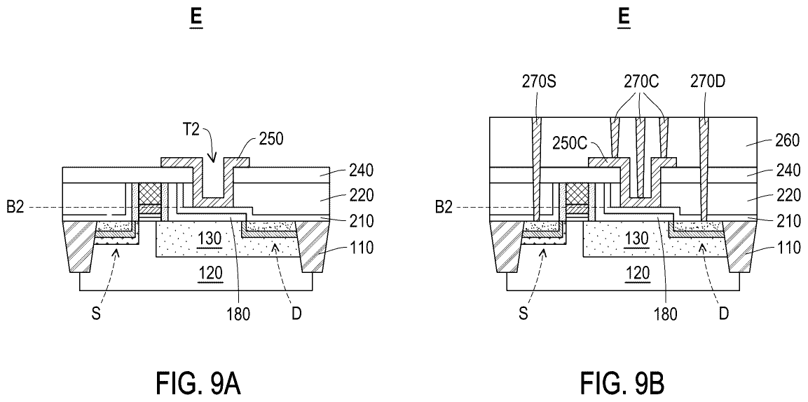

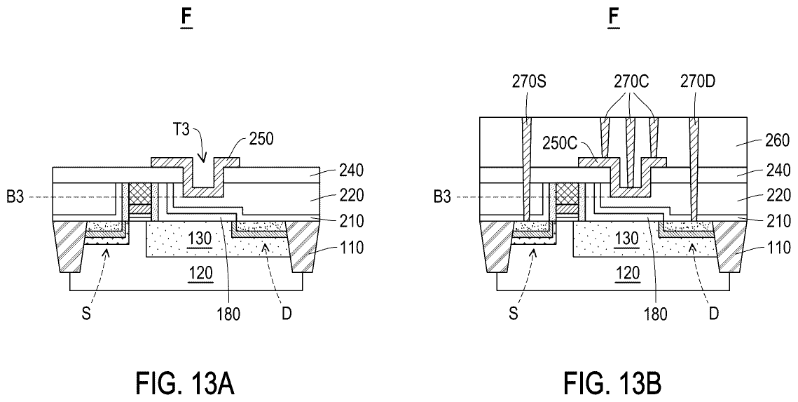

In addition to the above-mentioned that the high resistance field plate 250C completely located on the high resistance dielectric layer 240, after the processes of FIG. 1A to FIG. 1G, the trenches T1, T2, and T3 may be formed in the high resistance dielectric layer 240 and the lower interlayer layer 220 to form respectively the trenches T1, T2, and T3 shown in the high voltage device D shown in FIG. 5A, the high voltage device E shown in FIG. 9A, and the high voltage device F shown in FIG. 13A. The bottom B1 of the trench T1, the bottom B2 of the trench T2, and the bottom B3 of the trench T3 are respectively located on the sacrificial oxide layer 180, on the contact etching stop layer 210, and between the contact etching stop layer 210 and the high resistance dielectric layer 240. Then, a trench-type high resistance field plate 250C is formed on the bottom, sidewalls, and upper sides of the trenches T1, T2, and T3, as shown in FIG. 5A, FIG. 9A, and FIG. 13A.

That is, the bottom B1 of the high resistance field plate 250C of the high voltage device D shown in FIG. 5A is directly located on the sacrificial oxide layer 180; the bottom B2 of the high resistance field plate 250C of the high voltage device E shown in FIG. 9A is directly located on the contact etch stop layer 210; the bottom B3 of the high resistance field plate 250C of the high voltage device F shown in FIG. 13A is between the contact etch stop layer 210 and the high resistance dielectric layer 240.

Then, in a method similar to that shown in FIG. 1J, the upper interlayer dielectric layer 260, the source contact plug 270S, the high voltage device contact plug 270C and the drain contact plug 270D are formed shown in FIG. 5B, FIG. 9B and FIG. 13B. The high voltage device contact plug 270C may be formed one or more. Alternatively, as mentioned above, based on the requirement, only the upper interlayer dielectric layer 260, the source contact plug 270S and the drain contact plug 270D may be formed without forming the high voltage device contact plug 270C.

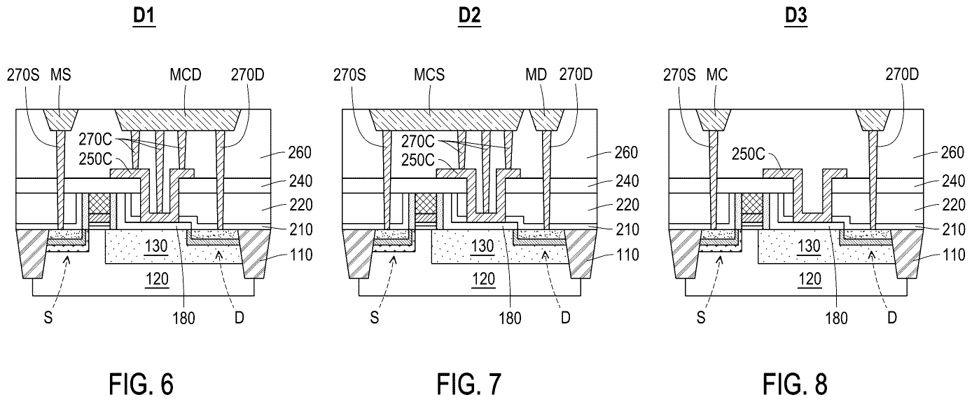

Next, please refer to FIG. 5B and FIG. 6 to FIG. 8 at the same time, which uses the process relative to FIG. 1J and FIG. 2 to FIG. 4. Regarding to the electrical connection design of the bottom B1 of the high resistance field plate 250C located directly on the sacrificial oxide layer 180, to form the high voltage device D1 as shown in FIG. 6, the high voltage device contact plug 270C and the drain contact plug 270D are electrically connected with the metal layer MCD; or, to form the high voltage device D2 as shown in FIG. 7, the high voltage device contact plug 270C and the source contact plug 270S are electrically connected with the metal layer MCS; or, to form the high voltage device D3 of the high resistance field plate 250C in the floating state, as shown in FIG. 8, the metal layer MC and the metal layer MD are only formed on the source contact plug 270S and the drain contact plug 270D respectively, and the high resistance field plate 250C is not electrically connected to the source contact plug 270S nor to the drain contact plug 270D.

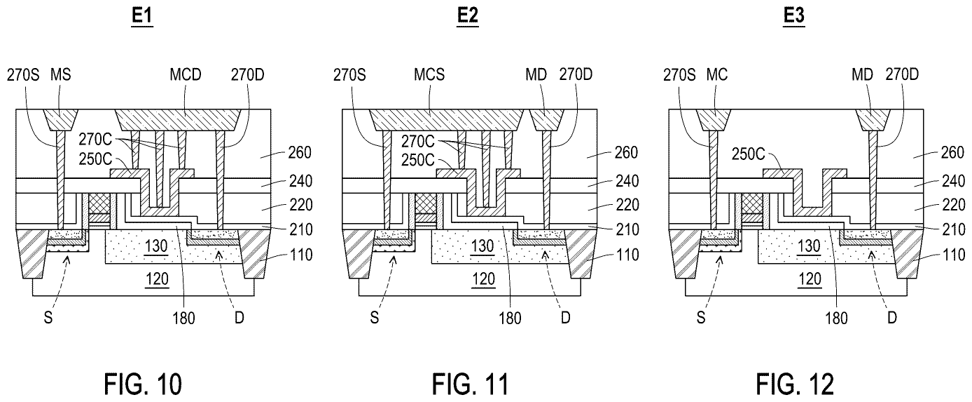

Alternatively, please refer to FIG. 9B and FIG. 10 to FIG. 12 at the same time, which uses the process relative to FIG. 1J and FIG. 2 to FIG. 4. Regarding to the electrical connection design of the bottom B2 of the high resistance field plate 250C located directly on the contact etch stop layer 210, to form the high voltage device E1 as shown in FIG. 10, the high voltage device contact plug 270C and the drain contact plug 270D are electrically connected with the metal layer MCD; or, to form the high voltage device E2 as shown in FIG. 11, the high voltage device contact plug 270C and the source contact plug 270S are electrically connected with the metal layer MCS; or, to form the high voltage device E3 of the high resistance field plate 250C in the floating state, as shown in FIG. 12, the metal layer MC and the metal layer MD are only formed on the source contact plug 270S and the drain contact plug 270D respectively, and the high resistance field plate 250C is not electrically connected to the source contact plug 270S nor to the drain contact plug 270D.

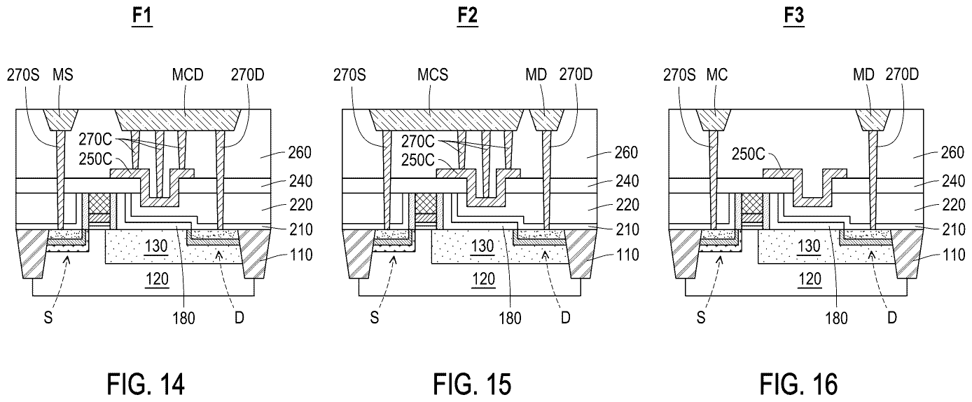

Alternatively, please refer to FIG. 13B and FIG. 14 to FIG. 16 at the same time, which uses the process relative to FIG. 1J and FIG. 2 to FIG. 4. Regarding to the electrical connection design of the bottom B3 of the high resistance field plate 250C located between the contact etch stop layer 210 and the high resistance dielectric layer 240, to form the high voltage device F1 as shown in FIG. 14, the high voltage device contact plug 270C and the drain contact plug 270D are electrically connected with the metal layer MCD; or, to form the high voltage device F2 as shown in FIG. 15, the high voltage device contact plug 270C and the source contact plug 270S are electrically connected with the metal layer MCS; or, to form the high voltage device F3 of the high resistance field plate 250C in the floating state, as shown in FIG. 16, the metal layer MC and the metal layer MD are only formed on the source contact plug 270S and the drain contact plug 270D respectively, and the high resistance field plate 250C is not electrically connected to the source contact plug 270S nor to the drain contact plug 270D.

The high voltage devices D1, D2, D3, E1, E2, E3, F1, F2 and F3 of the trench-type high resistance field plate 250C have a large process window due to their bottoms B1, B2 and B3, compared with a contact field plate, the chance of passing through the sacrificial oxide layer 180 during manufacturing is smaller. So the performance degradation of high voltage device using contact field plate may be reduced. In addition, compared with the high resistance field plate 250C formed only on the high resistance dielectric layer 240, the high resistance field plate 250C of a specific length may compress into a smaller space due to the trench-type high resistance field plate 250C. Therefore, the pitch of the devices can be reduced to achieve the purpose of forming smaller devices.

In summary, the semiconductor device of the disclosure replaces the traditional contact field plate with a high resistance field plate, which not only solves the problem of reduced performance of high voltage devices caused by the difficulty in controlling the position of the contact field plate, but also increases the breakdown voltage and the lower Rdson.

Furthermore, the method of forming semiconductor device provided by the disclosure has the advantages of being compatible with the high-k metal gate (HKMG) process and may form the above-mentioned semiconductor device without an additional mask.

Moreover, the above-mentioned semiconductor devices and their formation methods may also be used in various advanced processes, such as high-k metal gate planar field-effect transistor (HKMG planar FET), fin field-effect transistor (FinFET), gate-all-around nanosheet (GAA nanosheet), etc.

Although the disclosure has been disclosed above through embodiments, they are not intended to limit the disclosure. Any person with ordinary knowledge in the relevant technical field may make some modifications and modifications without departing from the spirit and scope of the disclosure. Therefore, the protection scope of the disclosure shall be determined by the appended patent application scope.

What is claimed is:

1. A semiconductor device, comprising:
a semiconductor substrate;
a gate structure on the semiconductor substrate;
a source region and a drain region in the semiconductor substrate and on opposite sides of the gate structure;
a sacrificial oxide layer on the semiconductor substrate;
a contact etch stop layer on the sacrificial oxide layer;
a lower interlayer dielectric layer on the contact etch stop layer;
a high resistance dielectric layer on the gate structure and the lower interlayer dielectric layer; and
a high resistance field plate, wherein at least a part of the high resistance field plate is on the high resistance dielectric layer.

2. The semiconductor device according to claim 1, wherein the high resistance field plate is completely on the high resistance dielectric layer.

3. The semiconductor device according to claim 1, wherein another part of the high resistance field plate is in the high resistance dielectric layer and the lower interlayer dielectric layer.

4. The semiconductor device according to claim 3, wherein a bottom of the other part of the high resistance field plate is directly on the sacrificial oxide layer.

5. The semiconductor device according to claim 3, wherein a bottom of the other part of the high resistance field plate is directly on the contact etch stop layer.

6. The semiconductor device according to claim 3, wherein a bottom of the other part of the high resistance field plate is between the contact etch stop layer and the high resistance dielectric layer.

7. The semiconductor device according to claim 1, further comprising:
an upper interlayer dielectric layer on the high resistance dielectric layer and the high resistance field plate;
a source contact plug in the upper interlayer dielectric layer, the high resistance dielectric layer, the lower interlayer dielectric layer and the contact etch stop layer, and electrically contacted to the source region;
a drain contact plug in the upper interlayer dielectric layer, the high resistance dielectric layer, the lower interlayer dielectric layer and the contact etch stop layer, and electrically contacted to the drain region; and
a high voltage device contact plug in the upper interlayer dielectric layer, and electrically contacted to the high resistance field plate,
wherein the high voltage device contact plug and the drain contact plug are electrically connected with a metal layer.

8. The semiconductor device according to claim 1, further comprising:
an upper interlayer dielectric layer on the high resistance dielectric layer and the high resistance field plate;
a source contact plug in the upper interlayer dielectric layer, the high resistance dielectric layer, the lower interlayer dielectric layer and the contact etch stop layer, and electrically contacted to the source region;
a drain contact plug in the upper interlayer dielectric layer, the high resistance dielectric layer, the lower interlayer dielectric layer and the contact etch stop layer, and electrically contacted to the drain region; and
a high voltage device contact plug in the upper interlayer dielectric layer, and electrically contacted to the high resistance field plate,
wherein the high voltage device contact plug and the source contact plug are electrically connected with a metal layer.

9. The semiconductor device according to claim 1, further comprising:
an upper interlayer dielectric (ILD) layer on the high resistance dielectric layer and the high resistance field plate;
a source contact plug in the upper interlayer dielectric layer, the high resistance dielectric layer, the lower interlayer dielectric layer and the contact etch stop layer, and electrically connected to the source region; and
a drain contact plug in the upper interlayer dielectric layer, the high resistance dielectric layer, the lower interlayer dielectric layer and the contact etch stop layer, and electrically connected to the drain region,
wherein the high resistance field plate is not electrically connected to the source contact plug nor to the drain contact plug.

10. The semiconductor device according to claim 1, wherein the gate structure comprises a metal gate.

11. The semiconductor device according to claim 1, wherein the high resistance field plate comprises titanium nitride (TiN).

12. A method of forming semiconductor device, comprising:
providing a semiconductor substrate;
forming a gate structure on the semiconductor substrate;
forming a source region and a drain region in the semiconductor substrate and on opposite sides of the gate structure;
forming a sacrificial oxide layer on the semiconductor substrate;
forming a contact etch stop layer on the sacrificial oxide layer;
forming a lower interlayer dielectric layer on the contact etch stop layer;
forming a high resistance dielectric layer on the gate structure and the lower interlayer dielectric layer; and
forming a high resistance field plate, wherein at least a part of the high resistance field plate is on the high resistance dielectric layer, and wherein another part of the high resistance field plate is in the high resistance dielectric layer and in the lower interlayer dielectric layer.

13. The method of forming semiconductor device according to claim 12, wherein a bottom of the other part of the high resistance field plate is directly on the sacrificial oxide layer.

14. The method of forming semiconductor device according to claim 12, wherein a bottom of the other part of the high resistance field plate is directly on the contact etch stop layer.

15. The method of forming semiconductor device according to claim 12, wherein a bottom of the other part of the high resistance field plate is between the contact etch stop layer and the high resistance dielectric layer.

16. The method of forming semiconductor device according to claim 12, further comprising:
forming an upper interlayer dielectric layer on the high resistance dielectric layer and the high resistance field plate;
forming a source contact plug in the upper interlayer dielectric layer, the high resistance dielectric layer, the lower interlayer dielectric layer and the contact etch stop layer, and electrically contacted to the source region ;
forming a drain contact plug in the upper interlayer dielectric layer, the high resistance dielectric layer, the lower interlayer dielectric layer and the contact etch stop layer, and electrically contacted to the drain region; and
forming a high voltage device contact plug in the upper interlayer dielectric layer, and electrically contacted to the high resistance field plate,
wherein the high voltage device contact plug and the drain contact plug are electrically connected with a metal layer.

17. The method of forming semiconductor device according to claim 12, further comprising:
forming an upper interlayer dielectric layer on the high resistance dielectric layer and the high resistance field plate;
forming a source contact plug in the upper interlayer dielectric layer, the high resistance dielectric layer, the lower interlayer dielectric layer and the contact etch stop layer, and electrically connected to the source region;
forming a drain contact plug in the upper interlayer dielectric layer, the high resistance dielectric layer, the lower interlayer dielectric layer and the contact etch stop layer, and is electrically connected to the drain region; and
forming a high voltage device contact plug in the upper interlayer dielectric layer, and electrically contacted to the high resistance field plate,
wherein the high voltage device contact plug and the source contact plug are electrically connected with a metal layer.

18. The method of forming semiconductor device according to claim 12, further comprising:
forming an upper interlayer dielectric layer on the high resistance dielectric layer and the high resistance field plate;
forming a source contact plug in the upper interlayer dielectric layer, the high resistance dielectric layer, the lower interlayer dielectric layer and the contact etch stop layer, and electrically connected to the source region; and
forming a drain contact plug in the upper interlayer dielectric layer, the high resistance dielectric layer, the lower interlayer dielectric layer and the contact etch stop layer, and electrically connected to the drain region,
wherein the high resistance field plate is not electrically connected to the source contact plug nor to the drain contact plug.

19. The method of forming semiconductor device according to claim 12, wherein the gate structure comprises a metal gate.

20. The method of forming semiconductor device according to claim 12, wherein the high resistance field plate comprises titanium nitride (TiN).
